(19) United States
(12) Patent Application Publication
(10) Pub. No.: US 2012/0229307 A1
(43) Pub. Date: Sep. 13, 2012

(54) LOW POWER WIRELESS SHORT RANGE TRANSMISSION SYSTEM

(76) Inventor: Chun-Liang TSAI, Hsinchu County (TW)

(21) Appl. No.: 13/045,514

(22) Filed: Mar. 10, 2011

(51) Int. Cl. H03K 17/94; H04L 27/04; H04L 27/20

(52) U.S. Cl. 341/22; 375/308; 375/300

(57) ABSTRACT

A wireless short range transmission system comprises a controller, a first oscillator, a transmitter, and an antenna. The transmitter comprises a phase-lock loop frequency synthesizer for receiving a reference signal from the first oscillator and a first modulation signal. The phase-lock loop frequency synthesizer is configured to be turned on by the first modulation signal for generating a carrier signal based on the reference signal. The transmitter further comprises a power amplifier for receiving the carrier signal from the phase-lock loop frequency synthesizer and a second modulation signal. The power amplifier is configured to be turned on/off by the second modulation signal to generate a modulated signal based on the carrier signal. The power amplifier is turned on after the phase-lock loop frequency synthesizer is stabilized and the phase-lock loop frequency synthesizer is turned off with the power amplifier or after the power amplifier has been turned off.

### BACKGROUND OF THE INVENTION

The present invention relates generally to low power wireless short range transmission and, more particularly, to a low power signal generation system for wireless short range transmission.

In the past few years, wireless short range transmission systems have become more commonly used in devices, such as remote controllers or wireless keyboards, for transmitting signals to other devices located within a short range. The transmission range of wireless short range transmission systems is generally less than 15 meters. For example, a remote controller or a wireless keyboard, in general, comprises a set of keys, a key matrix, a controller, a transmitter and a light emitting diode (LED) for transmitting infrared (IR) signals or an antenna for transmitting radio frequency (RF) signals. For instance, FIG. 1 is a block diagram of a conventional wireless keyboard 10. Referring to FIG. 1, the wireless keyboard 10 may include a set of keys (not shown), a key matrix 11 and a wireless short range transmission system. The wireless short range transmission system includes a controller 12, a crystal oscillator 13, a transmitter 14 (TX), and an antenna 15. The controller 12 is coupled to the key matrix 11, the crystal oscillator 13, and the transmitter 14. The crystal oscillator 13 is further coupled to the transmitter 14, and the transmitter 14 is further coupled to the antenna 15. The controller 12 may include a modulator 12-1 for generating modulation signals. In operation, the controller 12 may send and receive signals to and from the key matrix 11. For example, the controller 12 is configured to scan the key matrix 11 for signals which indicate that one or more keys are being pressed, and send an activation signal ACT1 and a modulation signal MOD to the crystal oscillator 13 and the transmitter 14, respectively. In response to the activation signal ACT1, the crystal oscillator 13 may generate a reference signal REF at a desired frequency, and feed the reference signal REF to the transmitter 14. The transmitter 14 may include a phase-lock loop (PLL) frequency synthesizer 14-1 and a power amplifier (PA) 14-2. The transmitter 14 may generate a modulated signal, based on the reference signal REF received from the crystal oscillator 13, and another activation signal ACT2 and a modulation signal MOD received from the controller 12. The modulated signal is subsequently transmitted by the antenna 15 as an RF signal.

FIG. 2 is a timing diagram describing the signals generated by the crystal oscillator 13, the PLL 14-1, the power amplifier 14-2 and the transmitter 14, after the controller 12 receives a signal from the key matrix 11 indicating that a key was pressed. First, the controller 12 may activate the crystal oscillator 13 in order to generate the reference signal REF at the desired frequency. Once the crystal oscillator 13 has stabilized, the controller 12 may activate the PLL 14-1 and the power amplifier 14-2. For example, the PLL 14-1 may first be activated by an activation signal ACT2 in order to generate a carrier signal based on the frequency indicated by the reference signal REF. Once the PLL 14-1 has stabilized, the power amplifier 14-2, which receives the carrier signal from the PLL 14-1, may be turned ON or OFF by a modulation signal MOD from the controller 12 thereby generating a modulated signal for transmission via the antenna 15 as an RF signal.

Conventional keyboards having wireless short range transmission systems similar to that described above may consume a significantly large amount of power. For instance, assuming information is transmitted at 1 kilobit per second (kbps), the bit time of logic high and logic low are the same (i.e., the duty cycle is 50%), the voltage of logic high and logic low are 2 volts (V) and 0 V, respectively, and the current for operating the crystal oscillator 13, PLL 14-1 and power amplifier 14-2 are 500 microamperes (μA), 5 milliamperes (mA), and 5 mA, respectively. Furthermore, for wireless short range transmission, the bit error rate is assumed to be low, and consideration of the current consumed during PLL lock time may be omitted since the time length of PLL lock time is relatively short in comparison to the time length of the command. Therefore, the average current for sending a logic high bit (1) and a logic low bit (0) would be approximately 8000 μA (i.e., (500 μA+5 mA+5 mA)×0.5+(500 μA+5 mA)×0.5). As a result, the energy efficiency would be approximately 16000 nanojoule per bit (nJ/bit) (i.e., 8000 μA×2 V/1 kbps). There has been proposed improvements for energy saving by designing around the PLL to create more energy efficient PLL, such as low power PLL. However, the PLL 14-1 stays turned on during the entire period of time for which the signal to be transmitted is being generated by the transmitter 14. In other words, the PLL 14-1 in such wireless short range transmission system consumes energy during generation of both logic ‘0’ & ‘1’. As a result, energy saved using energy efficient PLL is limited. It is, therefore, desired to have a wireless short range transmission system that may save even more energy while still utilizing the PLL, by increasing data rate and decreasing the operation time of the PLL.

In addition, as previously described, wireless short range transmission systems are commonly used in wireless keyboards. A wireless keyboard generally includes two types of keys. Each key of the first type is associated with a function itself. Examples of the first type keys include text keys, which are often laid out in QWERTY pattern, function keys (F1, F2, etc.), lock keys, navigation keys (up, down, etc.) and editing keys (delete, enter, etc.). The second type keys are modifier keys, which only function when simultaneously pressed with other key(s). Examples of keys of the second type include Ctrl, Alt, and Shift. In order to enter, for example, “A”, the user would first press “Shift” and then press “a”. As shown in FIG. 3, in a the conventional wireless keyboard, when “Shift” is pressed, the keyboard would transmit the key code for “Shift”, and when “a” is pressed, the keyboard would then transmit the key code for “A”. The receiver side, such as a computer, generally would not perform any action associated with the display when it receives the key code for “Shift”, since “Shift” itself is a meaningless command. The receiver would only carry out actions, such as displaying the character “A” on the display, when the key code for “A” is received. In other words, the key code for “Shift” sent by the wireless keyboard does not provide any significant function. Therefore, it is desired to have a wireless keyboard that may save energy by omitting data transmission when a second type key, such as “Shift”, is pressed alone. This is especially useful for users that are inexperienced with typing, and thus would press the “Shift” key for long duration of time. Also, for smaller devices, such as a handheld device, the duration which the user would hold on to the “Shift” key may also be longer, since it is more difficult to find the right text key on the small keyboard of the handheld device. The ability to save energy in small devices is even more significant and crucial.

In addition, many conventional keyboards use infrared (IR) signal devices for signal transmission. The amount of current for operating the LED light source alone, not including the current for operating the circuit, is often in the range of 40 to 100 mA. Furthermore, when using IR signal devices for signal transmission, the wireless keyboard needs to be to appropriately positioned with respect to the receiver since IR signal devices require line-of-sight to operate. It is therefore desirable to provide a wireless keyboard with a green wireless short range transmission system which may transmit signal with less power and which does not require line-of-sight to operate.

### BRIEF SUMMARY OF THE INVENTION

Examples of the present invention may provide a wireless short range transmission system comprising a controller, a first oscillator, a transmitter, and an antenna for transmitting the modulated signal. The transmitter comprises a phase-lock loop frequency synthesizer for receiving a reference signal from the first oscillator and a first modulation signal from the controller. The phase-lock loop frequency synthesizer is configured to be turned on by the first modulation signal for generating a carrier signal based on the reference signal. The transmitter further comprises a power amplifier for receiving the carrier signal from the phase-lock loop frequency synthesizer and a second modulation signal. The power amplifier is configured to be turned on and off by the second modulation signal in order to generate a modulated signal based on the carrier signal, wherein the power amplifier is turned on after the phase-lock loop frequency synthesizer is stabilized and the phase-lock loop frequency synthesizer is turned off with the power amplifier or after the power amplifier has been turned off.

Some examples of the present invention may also provide a wireless keyboard comprising the wireless short range transmission system described above, and a key matrix coupled to the controller.

Other objects, advantages and novel features of the present invention will be drawn from the following detailed embodiments of the present invention with attached drawings.

### BRIEF DESCRIPTION OF THE SEVERAL VIEWS OF THE DRAWINGS

The foregoing summary as well as the following detailed description of the preferred examples of the present invention will be better understood when read in conjunction with the appended drawings. For the purposes of illustrating the invention, there are shown in the drawings examples which are presently preferred. It is understood, however, that the invention is not limited to the precise arrangements and instrumentalities shown. In the drawings:

FIG. 1 is a block diagram of a conventional wireless keyboard 10.

FIG. 2 is a timing diagram describing the signals generated by the crystal oscillator 13, the PLL 14-1, the power amplifier 14-2 and the transmitter 14 in the conventional wireless keyboard of FIG. 1.

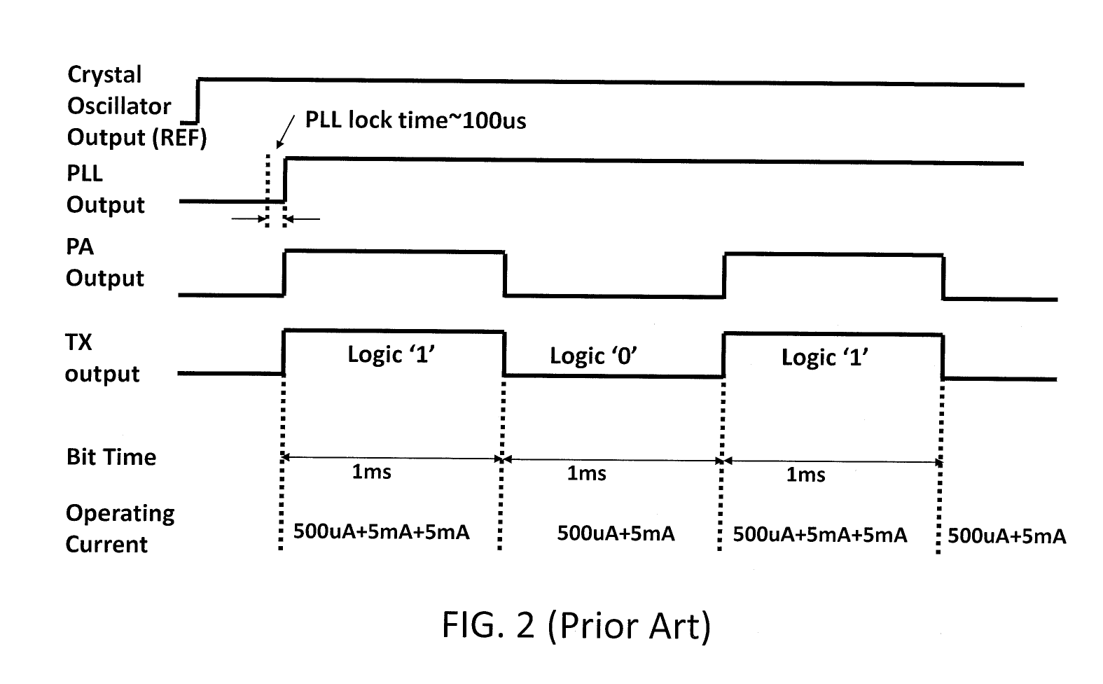

FIG. 3 is a timing diagram describing the signals transmitted by the wireless short range transmission system of the conventional wireless keyboard of FIG. 1.

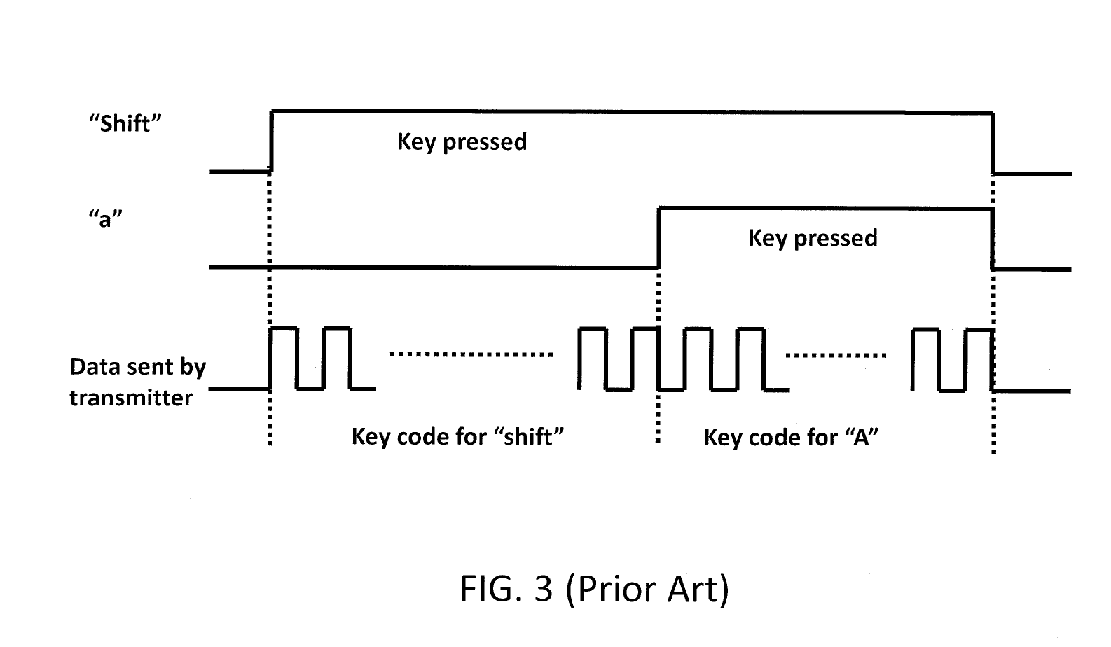

FIG. 4 is a block diagram of a wireless short range transmission system 20 in accordance with a first embodiment of the present invention.

FIG. 5 is a timing diagram describing the signals generated by the crystal oscillator 13, the PLL 24-1, the power amplifier 24-2 and the transmitter 24 shown in FIG. 4.

FIG. 6 is a block diagram of a wireless short range transmission system 30 in accordance with a second embodiment of the present invention.

FIG. 7 is a timing diagram describing the signals generated by the crystal oscillator 13, the fast-locking PLL 34-1, the power amplifier 24-2 and the transmitter 34 shown in FIG. 6.

FIG. 8 is a block diagram of a wireless keyboard 40 in accordance with a third and fourth embodiments of the present invention.

FIG. 9 is a flow chart of the method which the controller 42 as shown in FIG. 8 may perform to determine whether or not the transmitter 44 should be activated.

FIG. 10 is a timing diagram describing the signals received by the controller 42 from the key matrix 11 and the signal transmitted by the transmitter 44 according to the fourth embodiment of the present invention as shown in FIG. 8.

FIG. 11 describes a procedure for manufacturing the wireless keyboard as shown in FIG. 8.

FIG. 12 is a block diagram of a wireless keyboard 50 in accordance with a fifth embodiment of the present invention.

FIG. 13 is a schematic diagram illustrating an example of the memory 46 as shown in FIG. 12 and the relationship between the information stored in the memory 46 and the keys on the keyboard.

FIG. 14 describes a procedure for manufacturing the wireless keyboard as shown in FIG. 12.

### DETAILED DESCRIPTION OF THE INVENTION

Reference will now be made in detail to the present examples of the invention illustrated in the accompanying drawings. Wherever possible, the same reference numbers will be used throughout the drawings to refer to the same or like portions. It should be noted that the drawings are made in simplified form and are not drawn to precise scale.

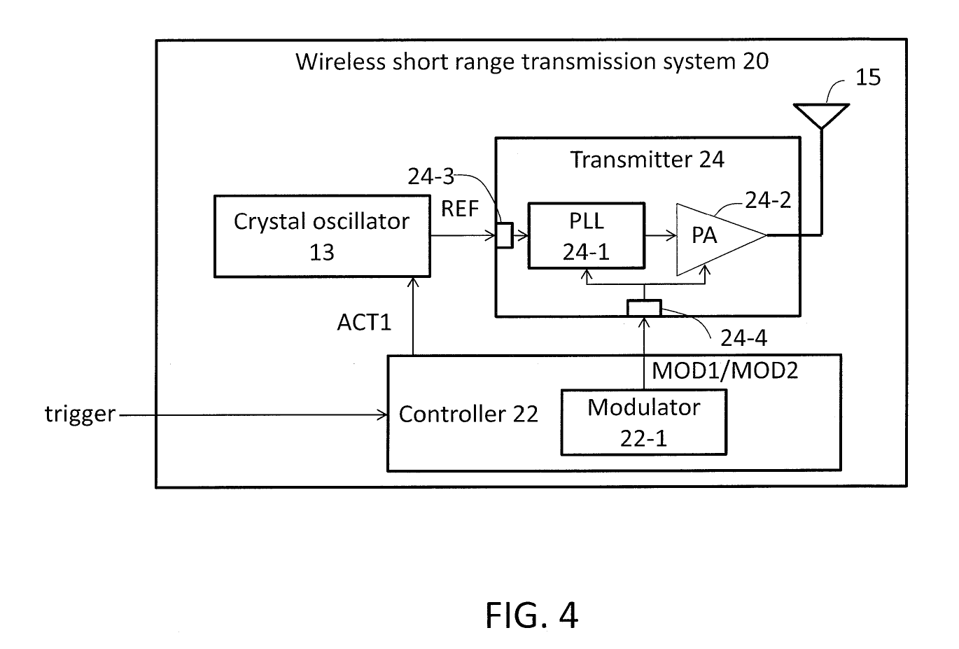

FIG. 4 is a block diagram of a wireless short range transmission system 20 in accordance with a first embodiment of the present invention. Referring to FIG. 4, wireless short range transmission system 20 may include a controller 22, a crystal oscillator 13, a transmitter 24 and an antenna 15 for transmitting radio frequency (RF) signals. The controller 22 may comprise a modulator 22-1 and the transmitter 24 may comprise a phase-lock loop (PLL) 24-1, a power amplifier (PA) 24-2, a frequency selection pin 24-3 and one or more modulation pin(s) 24-4. The controller 22 may be a microprocessor or a microcontroller. The modulator 22-1 may include one of an amplitude shift keying (ASK) modulator and an on-off keying (OOK) modulator. The PLL 24-1 is an integer-N PLL, which may be a digital PLL or an analog PLL.

In one example according to the present invention, the above-mentioned components of the system 20 may be integrated into a chip and the system 20 may take the form of an integrated circuit (IC). In another example, the system 20 may be formed as a part of an IC. Furthermore, the system 20 may be applicable to a human interface device (HID) such as a keyboard, a keypad on a cellular phone, a gamepad and a remote control.

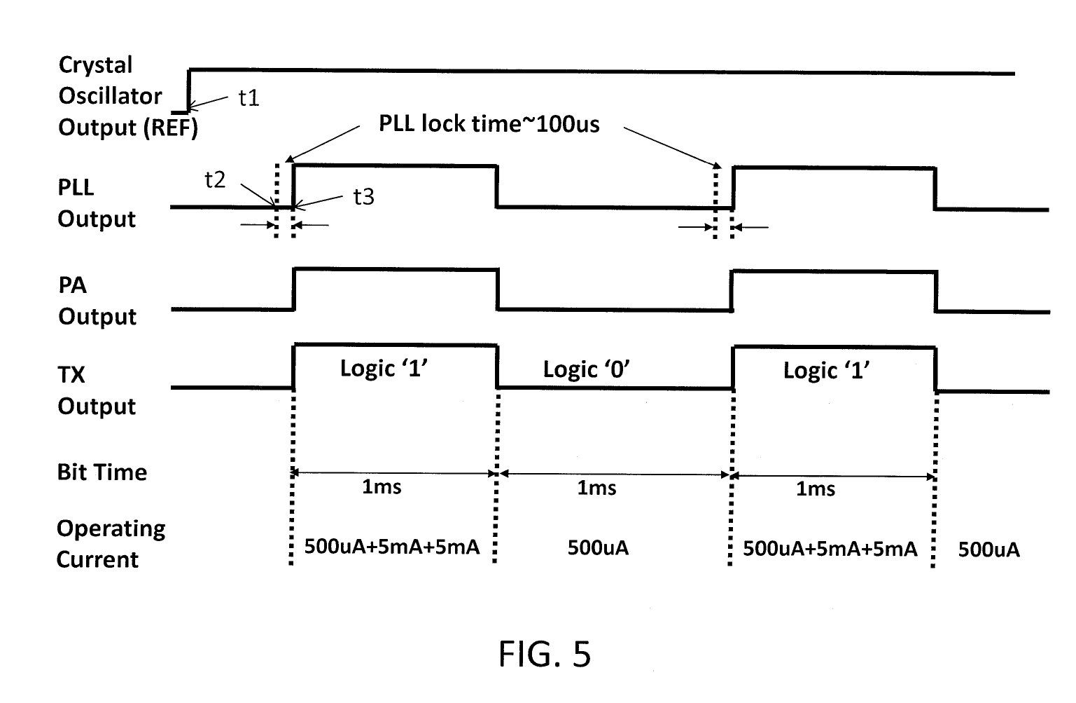

The controller 22 is coupled with the crystal oscillator 13 and the transmitter 24. When the controller 22 receives a trigger for activating the crystal oscillator 13 or transmitting modulated signals, the controller 22 may activate the crystal oscillator 13 with an activation signal ACT1, causing the crystal oscillator 13 to generate a reference signal REF, which is subsequently sent to the transmitter 24 via the frequency selection pin 24-3. The controller 22 may be configured to determine that the crystal oscillator 13 has stabilized by receiving a feedback signal (not shown) from the crystal oscillator 13 or have a counter (not shown) for counting a predetermined period of time. The predetermined period of time is the time that generally takes for the crystal oscillator 13 to stabilize, which may be determined based on experiments. Once the controller 22 has determined that the crystal oscillator 13 is stable, the controller 22 may cause the PLL 24-1 to generate a carrier signal based on the reference signal REF, and cause the transmitter to generate a modulated signal according to the method described below in reference to FIG. 5. Furthermore, since the controller 22 is a digital circuit, it requires a clock signal to operate. In one example, the controller 22 may comprise an internal oscillator (not shown) for generating the clock signal. Alternatively, the controller 22 may receive the clock signal from the external crystal oscillator 13. Moreover, in an alternate embodiment, the transmitter 24 may comprise another frequency selection pin (not shown) for receiving a signal from the controller 22 and sending the received signal to the PLL 24-1, so as to fine tune the frequency of the carrier signal generated by the PLL 24-1.

FIG. 5 is a timing diagram describing the signals generated by the crystal oscillator 13, the PLL 24-1, the power amplifier 24-2 and the transmitter 24 shown in FIG. 4, after the controller 22 receives the trigger. First, at a time point t1, the controller activates the crystal oscillator 13 to generate the reference signal REF, which is sent to the PLL 24-1 of the transmitter 24. Once the controller 22 determines that the crystal oscillator 13 has stabilized, the controller 22 may send a first modulation signal MOD1 generated by the modulator 22-1 to the PLL 24-1 via the modulation pin 24-4. The PLL 24-1 is activated by the first modulation signal MOD1 and may generate a carrier signal based on the frequency of the reference signal REF. The carrier signal is subsequently sent to the power amplifier 24-2. As shown in FIG. 5, the PLL 24-1 is activated at a time point t2 and is stabilized at a time point t3. The time it takes for the PLL 24-1 to stabilize may be approximately 100 microseconds (μs). The time may vary depending on the design of the PLL. The controller 22 may determine that the PLL 24-1 has stabilized by receiving a feedback signal (not shown) from the PLL 24-1 or have a counter (not shown) counting a predetermined period of time which the PLL 24-1 takes to stabilize, such as 100 μs. Once the controller 22 determines that the PLL 24-1 has stabilized, the power amplifier 24-2 may be turned on and off in response to, for example, the rising edge and the falling edge, respectively, of a second modulation signal MOD2, so as to generate a modulated signal based on the carrier signal and the second modulation signal MOD2. Accordingly, as illustrated in FIG. 5, the PA output may have the same waveform as the second modulation signal MOD2.

In one example, the PLL 24-1 may be turned off by the falling edge of the second modulation signal MOD2 along with the power amplifier 24-2. In another example, the PLL 24-1 may be turned off after the power amplifier 24-2 has been turned off. The first modulation signal MOD1 and second modulation signal MOD2 may be two signals that are the same in frequency and amplitude, but different in phase. In one example according to the present invention, the transmitter 24 may comprise a phase delaying circuit (not shown) which receives a single modulation signal from the controller 22, and generates the first modulation signal MOD1 and the second modulation signal MOD2. For example, the phase delaying circuit may comprise a buffer for causing delay to the received modulation signal, thus generating the second modulation signal MOD2 which is different from the received modulation signal in phase. In another example according to the present invention, the two modulation signals MOD1 and MOD2 are both generated by the modulator 22-1 and sent to the PLL 24-1 and the power amplifier 24-2 via different modulation pins 24-4.

The PLL 24-1 may include a voltage-controlled oscillator (VCO) and a divider, which are the most power consuming components of the PLL 24-1. Therefore, the PLL 24-1 may be turned off by having the VCO turned off. Once the VCO is turned off, the divider will also be turned off. The VCO may, in response to the first modulation signal from the controller 22, generate a carrier signal for the power amplifier 24-2. Subsequently, the modulated signal may be transmitted as an RF signal via the antenna 15 coupled with the transmitter 24.

Since the PLL 24-1 of the first embodiment of the present invention shown in FIG. 4 does not stay ON over the entire period of time during which the modulated signal is being generated, the wireless short range transmission system 20 according to the first embodiment of the present invention consumes much less energy and is more energy efficient than the wireless short range transmission systems in conventional wireless keyboards. Specifically, it may be assumed, again, that information are transmitted at 1 kbps, the bit time of logic high and logic low are the same (i.e., the duty cycle is 50%), the voltage of logic high and logic low are 2 V and 0 V, respectively, the current for operating the crystal oscillator 13, PLL 24-1 and power amplifier 24-2 are 500 μA, 5 mA, and 5 mA, respectively. Furthermore, PLL lock time is in general approximately 1/10 of the bit time. Therefore, the current consumed during PLL lock time is disregarded because the PLL lock time is short enough to be omitted in view of the length of the bit time. Furthermore, when the signal to be transmitted by the transmitter 24 is logic low, the most energy consuming component, PLL 24-1 is turned off by the modulation signal MOD1/MOD2 along with the power amplifier 24-2 or turned off after the power amplifier 24-2 has been turned off. As a result, the average current for sending a “1” and a “0” bit is only 5500 μA, which is 2500 μA less than the wireless short range transmission system in the conventional wireless keyboard 10 described above. The energy efficiency of the first embodiment of the present invention is thus approximately 11000 nJ/bit, which is 5000 nJ/bit less than the wireless short range transmission system in the conventional wireless keyboard 10 described above. In addition, the present invention transmits the modulated signals using RF signals, which is more energy efficient than transmitting the modulated signal using IR signals, and does not require line-of-sight for the wireless keyboard according to the present invention to operate. As a result, one skilled in the art should be able to understand that the first embodiment of the present invention requires less energy for transmitting information in comparison to conventional wireless short range transmission system.

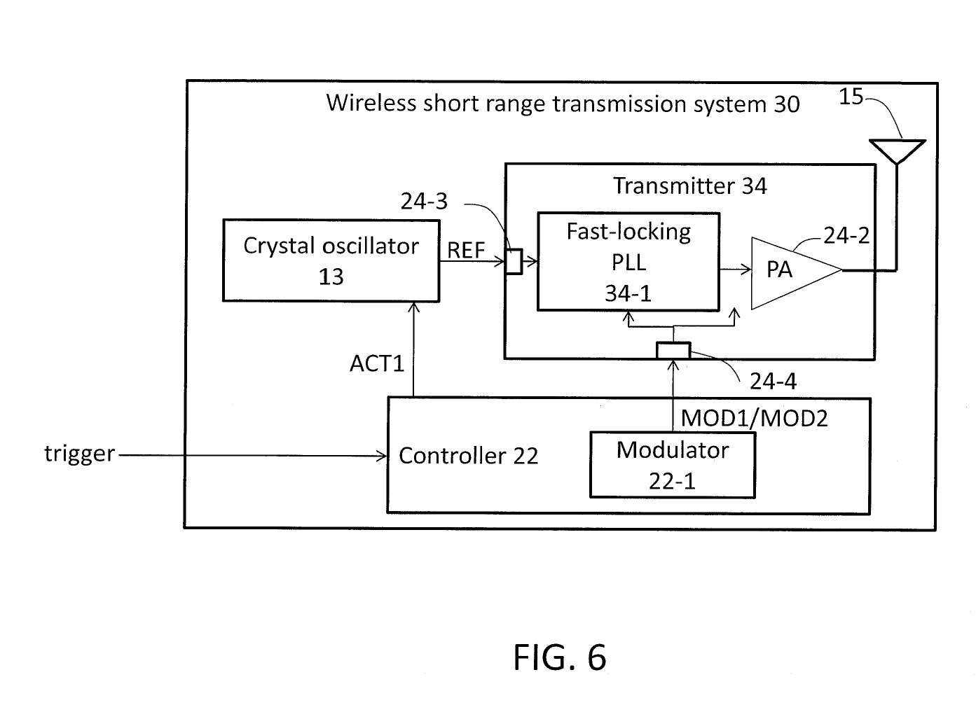

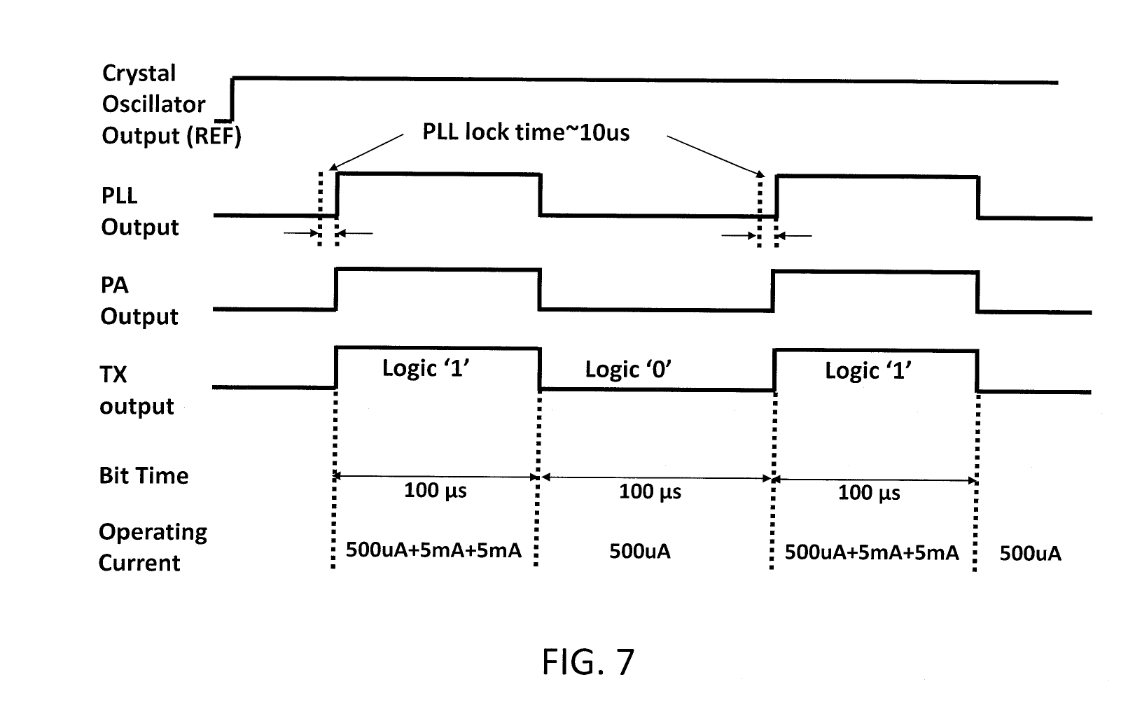

FIG. 6 is a block diagram of a wireless short range transmission system 30 in accordance with a second embodiment of the present invention. The second embodiment shown in FIG. 6 is similar to the first embodiment shown in FIG. 4, except that the second embodiment comprises a transmitter 34, which comprises a fast-locking PLL 34-1, instead of the PLL 24-1 of the first embodiment. The fast-locking PLL 34-1 has significantly shorter lock time compared to PLL 24-1, and may be a digital fast-locking PLL or an analog fast-locking PLL. An example of the fast-locking PLL 34-1 may be an integer-N PLL which incorporates additional components for decreasing the lock time. For example, there has been proposed to incorporate a digital discriminator aided phase detector (DAPD) in an integer-N PLL for expediting the loop settling. Another example of the fast-locking PLL 34-1 may be a fractional-N PLL, which has a more complicated structure than the integer-N PLL, but a shorter lock time. When the lock time is shorter, the bit rate may be increased, and thereby increasing the energy efficiency of the wireless short range transmission system 30 as described below in reference to FIG. 7. The operation method of the second embodiment is the same or similar to that of the first embodiment.

FIG. 7 is a timing diagram describing the signals generated by the crystal oscillator 13, the fast-locking PLL 34-1, the power amplifier 24-2 and the transmitter 34 shown in FIG. 6, after the controller 22 receives the trigger. As shown in FIG. 7, the lock time of the fast-locking PLL 34-1 is approximately 10 μs, which is 10 times shorter than the lock time of PLL 24-1. As a result, the bit rate of the transmitter 34 of the second embodiment is 10 kbps, which is ten times higher than the bit rate of the transmitter 24 of the first embodiment. As a result, while, the average current for sending a “1” and a “0” bit according to the second embodiment of the present invention is also 5500 μA, since the bit rate has increased by ten times as a result of shorter lock time, the energy efficiency of the second embodiment of the present invention is approximately 1100 nJ/bit, which is ten times more efficient than the first embodiment. In other words, the second embodiment of the present invention uses even less energy for transmitting information.

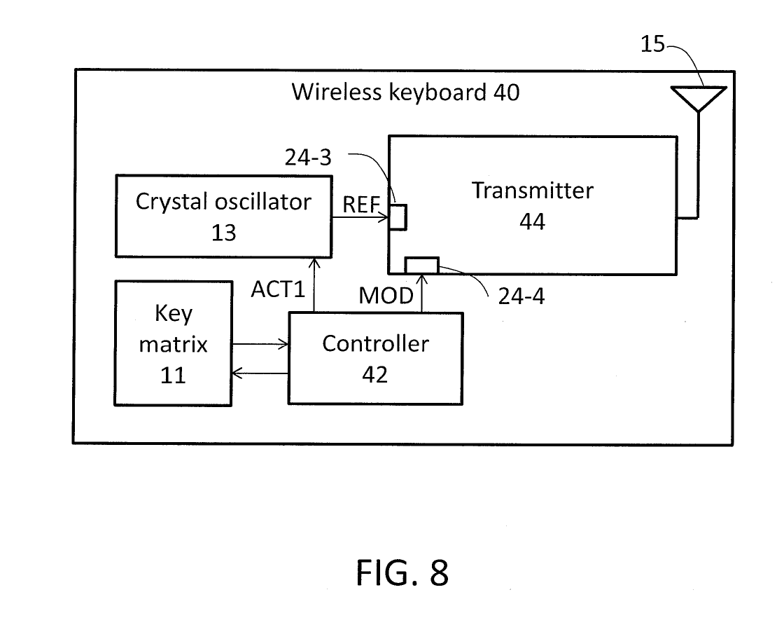

FIG. 8 is a block diagram of a wireless keyboard 40 in accordance with a third embodiment of the present invention. The wireless keyboard 40 comprises a wireless short range transmission system similar to or the same as the wireless short range transmission systems according to the first and second embodiments shown in FIGS. 4 and 6. The wireless keyboard 40 further comprises a key matrix 11 and a set of keys (not shown) connected to the key matrix 11. The controller 42 is configured to scan the key matrix 11 for one or more signals indicating that one or more keys are being pressed. If one or more signals indicating that one or more keys are being pressed are received by the controller 42, the controller 42 may cause the wireless short range transmission system to generate and transmit modulated signals in a method similar to or the same as the method of the wireless short range transmission systems according to the first and second embodiments.

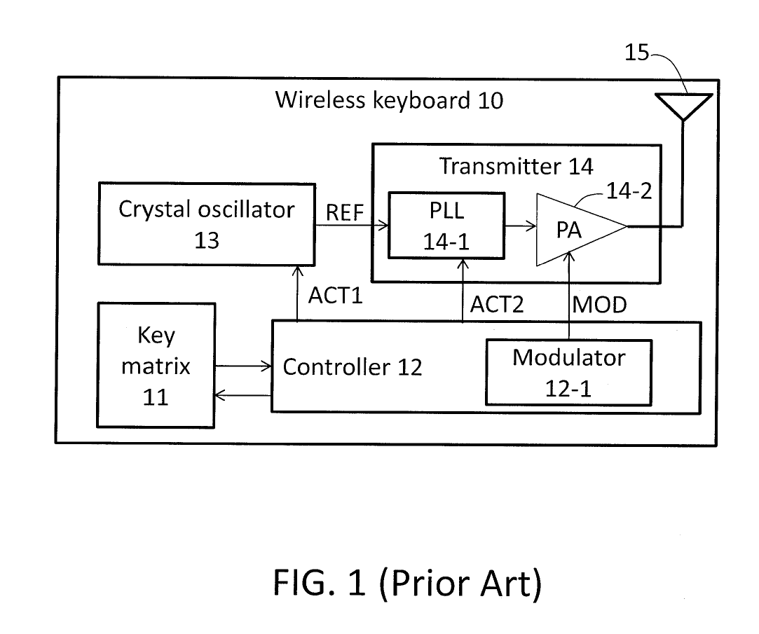

A fourth embodiment of the present invention is a wireless keyboard having the same components as the wireless keyboard 40, except that the transmitter 44 of the fourth embodiment may be the same or similar to one of the transmitter 14 as shown in FIG. 1, the transmitter 24 as shown in FIG. 4 or the transmitter 34 as shown in FIG. 6. The operation method of the fourth embodiment is the same or similar to that of the third embodiment, except that the controller 42 of the fourth embodiment is configured to activate the crystal oscillator 13 and the transmitter 44 in response to selective signals received from the key matrix 11. For example, the controller 42 of the fourth embodiment may be configured to determine whether the one or more signals received correspond to one or more keys of the first or second type, and thereby determining whether or not to activate the crystal oscillator 13 and the transmitter 44 for transmitting information. Each key of the first type is associated with a function itself. Examples of the first type keys include text keys, which are often laid out in QWERTY pattern, function keys (F1, F2, etc.), lock keys, navigation keys (up, down, etc.) and editing keys (delete, enter, etc.). The second type keys are modifier keys, which only function when simultaneously pressed with other key(s). Examples of keys of the second type include Ctrl, Alt, and Shift.

If the received signal(s) corresponds to a key of the first type, the controller 42 will proceed to trigger the crystal oscillator 13 and the transmitter 44 in the same or similar manner as that of the first and second embodiments. However, if the received signal(s) corresponds to one key of the second type only, the controller 42 will not send any signals to activate the crystal oscillator 13 or the transmitter 44. Instead, the controller 42 will wait for subsequent signal(s) from the key matrix 11. While the controller 42 waits for subsequent signal(s), the controller 42 may power-off itself entirely or turn off certain components in it. In an alternative example of the fourth embodiment, the crystal oscillator 13 is first activated when a signal indicating that a key has been pressed is received by the controller 42, and the transmitter 44 is only activated subsequently if it is determined that the one or more signals received correspond to one or more keys of the first or second type.

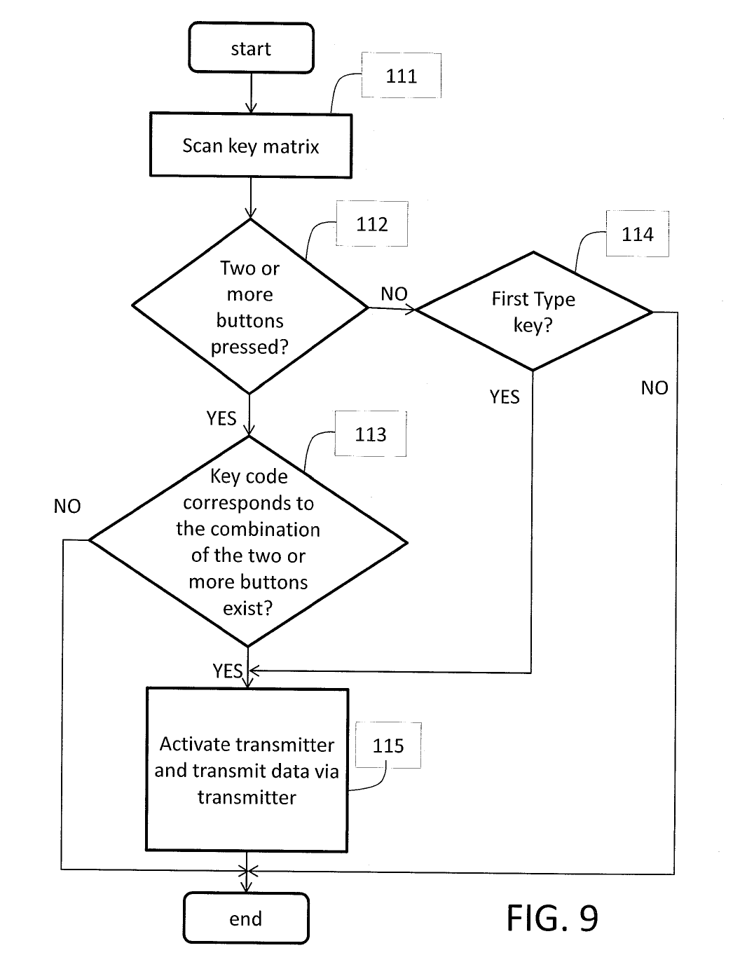

FIG. 9 is a flow chart of the method which the controller 42 may perform to determine whether or not signals should be sent out to activate the transmitter 44, after the digital controller 42 receives one or more signals from the key matrix 11 indicating one or more keys are being pressed. In step 111, the controller 42 scans the key matrix 11. In step 112, the controller 42 determines whether or not two or more keys are being pressed. If two or more keys are being pressed, the controller 42 proceeds to step 113 to determine whether there exists a key code that corresponds to the combination of the two or more pressed keys. For example, the combination of “Shift” and “a” corresponds to the key code “A”, while the combination of “Alt” and “Shift” may not correspond to any key code. If there exists a key code that corresponds to the combination of the two or more pressed keys, the controller 42 proceeds to activate both the crystal oscillator 13 and the transmitter 44 or just the transmitter 44 if the crystal oscillator 13 has already been activated, and transmit data via the transmitter 44 in step 115. The controller 42 may activate the crystal oscillator 13 and the transmitter 44 and transmit the key code corresponding to the combination of the two or more pressed keys via the transmitter 44 according to any one of the methods described above in relation to the first and second embodiments shown in FIGS. 4 to 7. On the other hand, if at step 113, the controller 42 determines that there does not exist any key code that corresponds to the combination of the two or more pressed key, the controller 42 does not activate the transmitter 44.

At step 112, if the controller 42 determines that only one key is being pressed, the controller 42 proceeds to step 114 to determine whether the pressed key is a key of the first type or the second type. If the pressed key is a first type key, the controller 42 may proceed to step 115. Otherwise, if the pressed key is a second type key, the controller 42 does not activate the transmitter 44. At the end, the controller 42 may either stay idle or power-off itself until another signal is received from the key matrix 11.

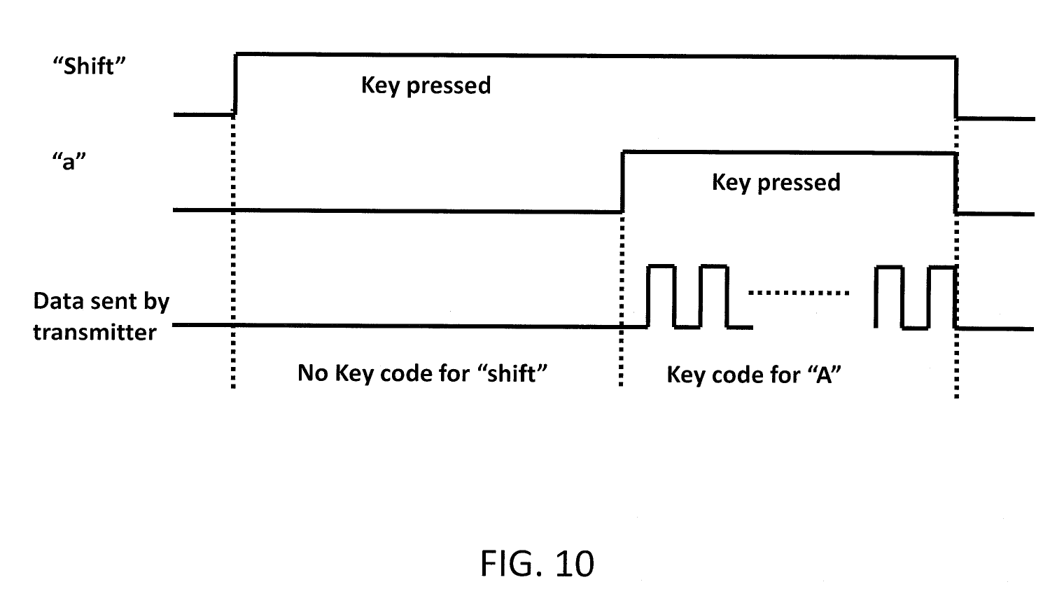

FIG. 10 is a timing diagram describing the signals received by the controller 42 from the key matrix 11 and the signal transmitted by the transmitter 44. As shown in FIG. 10, when a “Shift” key, which is one of the second type keys, is pressed, no data is being sent by the transmitter 44. Subsequently, when both the “Shift” key and the “a” key are pressed and it is determined that the combination of the two keys correspond to “A”, the transmitter 44 sends out the key code for “A”. In one example, when the controller 42 receives a signal indicating that one or more keys are being pressed, the controller 42 may send the first activation signal ACT1 to the crystal oscillator 13, in order to cause the crystal oscillator 13 to generate a reference signal REF. Subsequently, the controller 42 may scan the key matrix 11 to determine which key(s) are being pressed. For example, if both the “Shift” key signal and the “a” key signal from the key matrix 11 are received by the controller 42, the controller 42 may send a modulation signal indicating the key code for “A” to the transmitter 44, after the crystal oscillator 13 has stabilized.

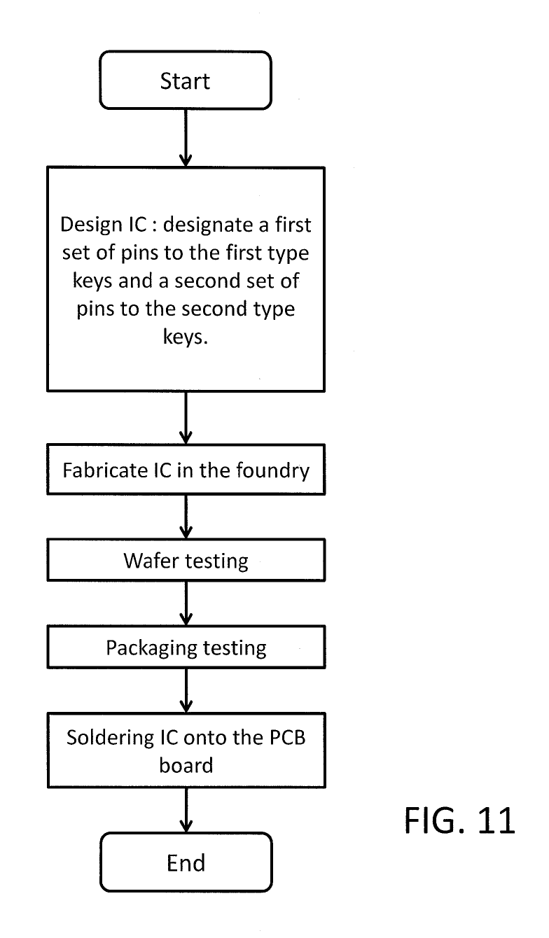

The circuitry of the wireless keyboard 40 generally comprises a printed circuit board (PCB) and an IC chip. The manufacturing of the wireless keyboard 40 generally comprises the steps of fabricating the IC on a wafer in the foundry, testing the wafer, packaging the IC, and soldering the IC onto the PCB board. The PCB board is generally designed according to the application of the PCB board. FIG. 11 describes a procedure for manufacturing the wireless keyboard 40 according to an example of the present invention. When the IC is being designed, a first number of pins are designated to be associated with the first type keys, and a second number of pins are designated to be associated with the second type keys. Subsequently, the IC is fabricated in the foundry according to the IC design. Based on the pin assignment of the IC fabricated in the foundry, a customer may design a low-power keyboard or keypad with keys of the first type or second type on a printed circuit board (PCB). PCBs of the customer may then be manufactured accordingly. The controller 42 in the wireless keyboard 40 manufactured according to the method described above will thus be able to determine whether the signal received from the key matrix 11 represents a first type key or a second type key, and determine whether or not to transmit signals via the transmitter 44 according to the method described above in association with FIG. 9.

The wireless keyboard 40 according to the present invention may operate in at least one of the following two modes: active mode, which is when the user is using the wireless keyboard 40 to send information, and standby mode, which is when the user is not using the wireless keyboard 40. When the wireless keyboard 40 operates in active mode, the controller 42 repeatedly perform the method described in FIG. 9 until a predetermined period of time has lapsed, during which no signal was received by the controller 42 from the key matrix 11. After the predetermined period of time has lapsed, the wireless keyboard 40 switches to standby mode. While the wireless keyboard 40 is in standby mode, the power of all the components in the wireless keyboard may be turned off. When the controller 42 receives a signal from the key matrix 11 while it is in standby mode, the controller 42 switches to active mode and starts the process described in FIG. 9.

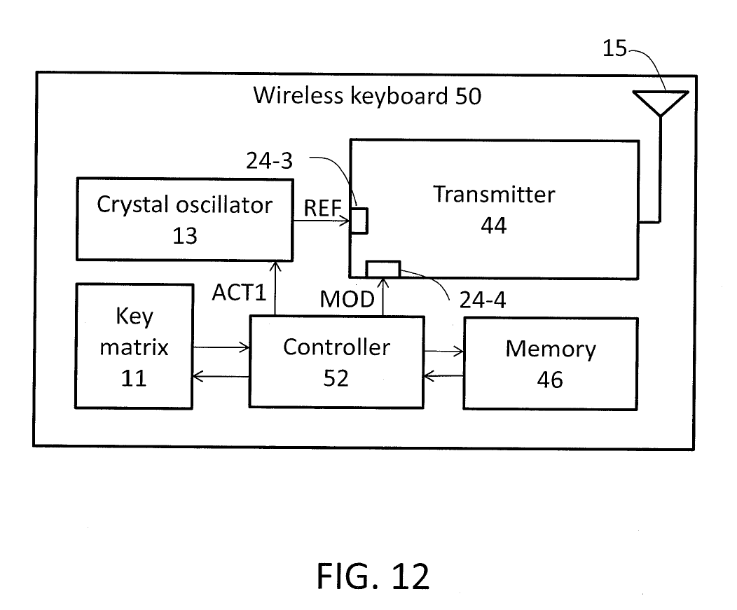

FIG. 12 is a block diagram of a wireless keyboard 50 in accordance with a fifth embodiment of the present invention. The wireless keyboard 50 is similar to the wireless keyboard 40 according to the fourth embodiment of the present invention, except that the wireless keyboard 50 further comprises a memory 46, which has prestored therein information regarding the mapping information of the keys with respect to the addresses of the memory, and information indicating each key as a first type key or a second type key. The controller 52 is configured to determine, based on the one or more signals received from the key matrix 11 and the information prestored in the memory 46, whether the one or more signals received correspond to one or more keys of the first or second type.

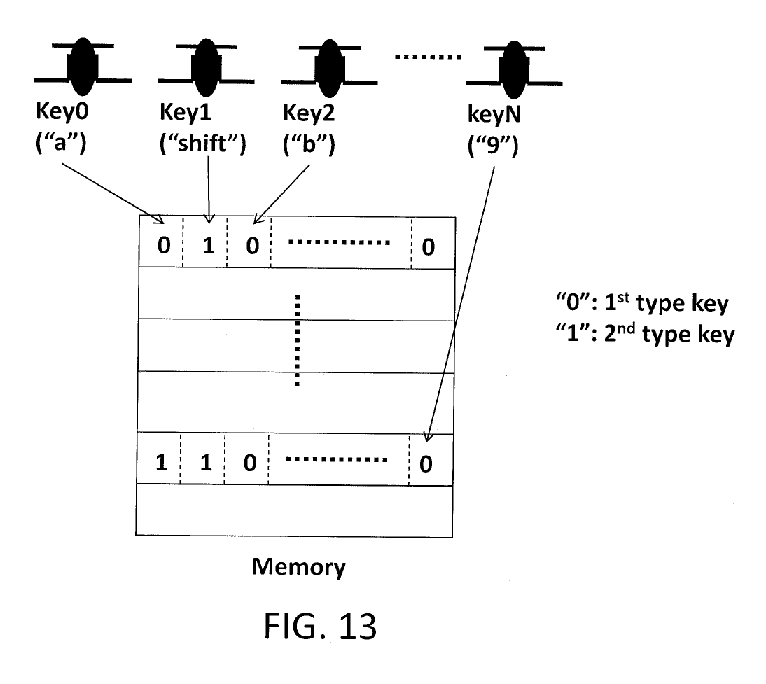

FIG. 13 is a diagram illustrating an example of the memory 46 and the relationship between the information stored in the memory 46 and the keys on the keyboard 50. Each key on the keyboard 50 is mapped to an address in the memory 46. The content at each address indicates whether the key to which the address corresponds is a key of the first or second type. For example, “0” may represent a key of the first type, and “1” may represent a key of the second type.

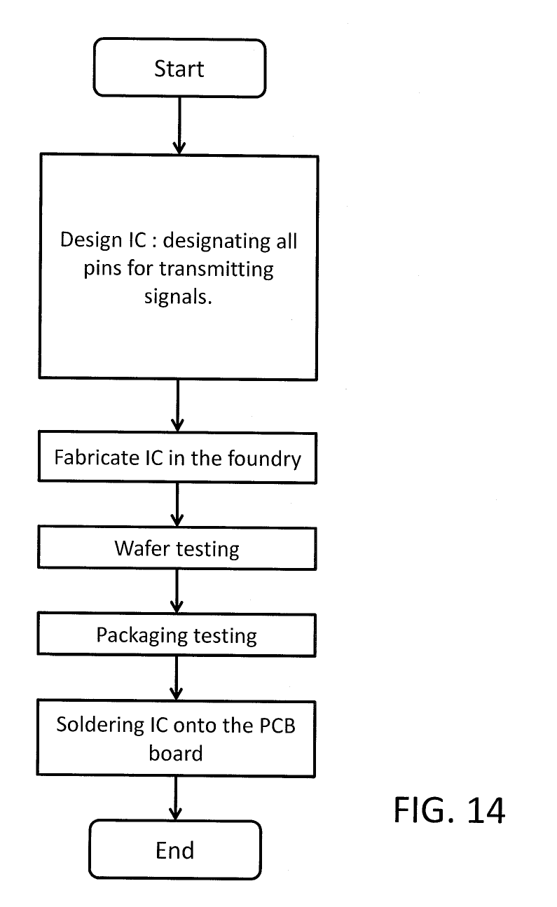

FIG. 14 describes a procedure for manufacturing of the wireless keyboard 50 according to an example of the present invention. The position of each key on the PCB board is decided during the design stage by the customer or application, and the PCB board is manufactured accordingly. When the IC is being designed, all the keys are designed to be able to transmit signals, because wiring each key according to its type during the stage when the PCB board is designed may be complicated and limited due to the intricacies and complicated structure of wiring. The IC is fabricated in the foundry according to the IC design. Information regarding the position and type of each key may be recorded into the memory 46 during wafer testing, IC packaging or after soldering of the IC onto the PCB board. By manufacturing the wireless keyboard in accordance with the procedure described above, the keyboard may be customized according to the application and the needs of the customer. For example, the layout of the keyboards for handheld devices may be different from those for desktop or laptop computers. Hence, the position of the keys on each keyboard may be different. With the procedure described above, the IC may be designed so that all the keys are capable of transmitting signals. Once the customer or application of the keyboard has been decided, the non-transmission property of the second type keys may be implemented by recording information into the memory during wafer testing, IC packaging or after soldering of the IC onto the PCB board. Therefore, providing energy efficient wireless keyboards to keyboards of different sizes.

In describing representative examples of the present invention, the specification may have presented the method and/or process of operating the present invention as a particular sequence of steps. However, to the extent that the method or process does not rely on the particular order of steps set forth herein, the method or process should not be limited to the particular sequence of steps described. As one of ordinary skill in the art would appreciate, other sequences of steps may be possible. Therefore, the particular order of the steps set forth in the specification should not be construed as limitations on the claims. In addition, the claims directed to the method and/or process of the present invention should not be limited to the performance of their steps in the order written, and one skilled in the art can readily appreciate that the sequences may be varied and still remain within the spirit and scope of the present invention.

It will be appreciated by those skilled in the art that changes could be made to the examples described above without departing from the broad inventive concept thereof. It is understood, therefore, that this invention is not limited to the particular examples disclosed, but it is intended to cover modifications within the spirit and scope of the present invention as defined by the appended claims.

We claim:

1. A wireless short range transmission system comprising:
a controller;
a first oscillator;
a transmitter that comprises:
a phase-lock loop frequency synthesizer for receiving a reference signal from the first oscillator and a first modulation signal from the controller, wherein the phase-lock loop frequency synthesizer is configured to be turned on by the first modulation signal for generating a carrier signal based on the reference signal; and
a power amplifier for receiving the carrier signal from the phase-lock loop frequency synthesizer and a second modulation signal, wherein the power amplifier is configured to be turned on and off by the second modulation signal in order to generate a modulated signal based on the carrier signal, wherein the power amplifier is turned on after the phase-lock loop frequency synthesizer is stabilized and the phase-lock loop frequency synthesizer is turned off with the power amplifier or after the power amplifier has been turned off; and
an antenna for transmitting the modulated signal.

2. The system of claim 1, wherein
the transmitter further comprises a frequency selection pin and at least one modulation pin; and
the phase-lock loop frequency synthesizer receives the reference frequency signal from the first oscillator via the frequency selection pin and receives the first modulation signal from the controller via a first pin of the at least one modulation pin.

3. The system of claim 2, wherein
the power amplifier receives the second modulation signal from the controller via a second pin of the at least one modulation pin; and
the controller comprises one of an amplitude shift keying (ASK) and an on-off keying (OOK) modulator for generating the first modulation signal and the second modulation signal, wherein the first modulation signal and the second modulation signal are the same in frequency and amplitude and different in phase.

4. The system of claim 2, wherein
the controller comprises one of an ASK modulator and an OOK modulator for generating the first modulation signal; and
the transmitter further comprises a phase delaying circuit for receiving the first modulation signal and generating the second modulation signal, wherein the first modulation signal and the second modulation signal are the same in frequency and amplitude and different in phase.

5. The system of claim 2, wherein the controller is configured to:
send an activation signal to the first oscillator for activating the first oscillator;
send the first modulation signal to the at least one modulation pin to activate the phase-lock loop frequency synthesizer in one of the situations:
(i) when the controller receives a first feedback signal from the first oscillator indicating the first oscillator has stabilized, and
(ii) after a first predetermined period of time, the first predetermined period of time being a time for the first oscillator to stabilize; and
send the second modulation signal to the power amplifier in one of the situations:
(i) when the controller receives a second feedback signal from the phase-lock loop synthesizer indicating the phase-lock loop has stabilized, and
(ii) after a second predetermined period of time, the second predetermined period of time being a time for the phase-lock loop synthesizer to stabilize.

6. The system of claim 1, wherein
the controller includes one of a microprocessor and a microcontroller;
the phase-lock loop frequency synthesizer includes one of a digital phase-lock loop frequency synthesizer, an analog phase-lock loop frequency synthesizer, a digital fast-locking PLL and an analog fast-locking PLL, wherein the phase-lock-loop frequency synthesizer further comprises a second oscillator, and the phase-lock loop synthesizer is turned on or off by turning on or off the second oscillator; and
the modulated signal is transmitted as a radio frequency signal.

7. A wireless keyboard comprising:
a controller;
a first oscillator;
a transmitter that comprises:
a phase-lock loop frequency synthesizer for receiving a reference signal from the first oscillator and a first modulation signal from the controller, wherein the phase-lock loop frequency synthesizer is configured to be turned on by the first modulation signal for generating a carrier signal based on the reference signal;
a power amplifier for receiving the carrier signal from the phase-lock loop frequency synthesizer and a second modulation signal, wherein the power amplifier is configured to be turned on and off by the second modulation signal in order to generate a modulated signal based on the carrier signal, wherein the power amplifier is turned on after the phase-lock loop frequency synthesizer is stabilized and the phase-lock loop frequency synthesizer is turned off with the power amplifier or after the power amplifier has been turned off; and
an antenna for transmitting the modulated signal; and
a key matrix coupled to the controller.

8. The wireless keyboard of claim 7 further comprising:
a plurality of keys coupled to the key matrix, wherein the plurality of keys comprise a set of first type keys and a set of second type keys, each of the first type keys is associated with one of a plurality of predetermined functions;
wherein the controller is further configured to:
receive a first signal from the key matrix indicating at least one of the plurality of keys has been selected,
determine, based on the first signal, if the selected at least one of the plurality of keys is one of the first type keys, and
activate the transmitter for transmitting the modulated signal via the antenna if the selected at least one of the plurality of keys is one of the first type keys, wherein the modulated signal carries information corresponding to the one of the plurality of predetermined function associated with the selected at least one of the plurality of keys.

9. The wireless keyboard of claim 8, wherein the controller is further configured to:
determine whether or not the selected at least one of the plurality of keys comprises two or more keys, and
if the selected at least one of the plurality of keys comprises two or more keys, the controller is further configured to determine if the combination of the two or more keys corresponds to one of the plurality of predetermined functions, and activate the transmitter for transmitting the modulated signal via the antenna if the combination of the two or more keys is associated with one of the plurality of predetermined functions, wherein the modulated signal carries information corresponding to the one of the plurality of predetermined function associated with the combination of the two or more keys.

10. The wireless keyboard of claim 9, wherein
each of the second type keys is associated with one of the plurality of predetermined functions only when the each of the second type keys is selected with at least another one of the plurality of keys.

11. The wireless keyboard of claim 10, wherein
the set of first type keys includes at least one of alphabets, number, symbols, punctuation keys, enter, backspace, tab, and caps lock keys, and the set of second type keys includes at least one of control, shift, and alt keys.

12. The wireless keyboard of claim 8 further comprising
a memory, coupled to the controller, for storing predetermined information indicating each of the plurality of keys as one of the first type keys or one of the second type keys, wherein
the controller determines if the selected at least one of the plurality of keys is one of the first type keys based on the first signal and the predetermined information.

13. The wireless keyboard of claim 12, wherein
the memory comprises a plurality of memory locations, each memory location is identified by a memory address, the memory is configured to store predetermined mapping information associated with the plurality of keys and the plurality of memory locations, each of the plurality of memory locations stores a flag indicating the corresponding key as the first type key or the second type key.

14. A wireless short range transmission system comprising:
an oscillator to generate a reference clock signal;
a controller to send a first modulation signal and a second modulation signal following the first modulation signal;
a phase-lock loop frequency synthesizer to be turned on in response to the first modulation signal and turned off in response to a falling edge of the second modulation signal, the phase-lock loop frequency synthesizer to generate a carrier signal based on the reference clock signal; and
a power amplifier to generate a modulated signal based on the carrier signal, the power amplifier to be turned on in response to a rising edge of the second modulation signal and turned off in response to a falling edge of the second modulation signal.

15. The system of claim 14, wherein the controller is configured to send the first modulation signal when the oscillator is stabilized.

16. The system of claim 14, wherein the controller is configured to send an activation signal to activate the oscillator and then send the first modulation signal after a predetermined period of time.

17. The system of claim 14, wherein the controller is configured to send the second modulation signal when the phase-lock loop frequency synthesizer is stabilized.

18. The system of claim 14, wherein the controller is configured to send the second modulation signal after a predetermined period of time for the phase-lock loop frequency synthesizer to become stabilized.

19. The system of claim 14, wherein the controller is coupled to a keyboard matrix that is coupled to a set of first type keys, each of which is associated with one of a plurality of functions, and a set of second type keys, each of which serves as a modifier key for the first type keys and other second type keys.

20. The system of claim 19, wherein the controller is configured to determine whether at least one of the first type keys is selected and cause the transmission of a modulated signal that carries information corresponding to the one of the plurality of predetermined functions associated with the selected at least one of the first type keys.
